(19) United States
(12) Patent Application Publication
(10) Pub. No.: US 2024/0368420 A1
(43) Pub. Date: Nov. 7, 2024

(54) ELECTRICALLY CONDUCTIVE ELASTOMERIC PRINTING INK FOR CONTACTLESS PRINTING PROCESSES

(71) Applicant: WACKER CHEMIE AG, Munchen (DE)

(72) Inventors: Sabin-Lucian SURARU, München (DE); Andreas KÖLLNBERGER, München (DE)

(73) Assignee: WACKER CHEMIE AG, Munchen (DE)

(21) Appl. No.: 18/686,454

(22) PCT Filed: Oct. 13, 2021
(86) PCT No.: PCT/EP2021/078319

§ 371 Date: Feb. 26, 2024

(51) Int. Cl. C09D 11/52; C09D 11/037; C09D 11/102; H05K 1/09; H05K 3/12

(52) U.S. Cl. CPC C09D 11/52; C09D 11/037; C09D 11/102; H05K 1/095; H05K 3/1275

(57) ABSTRACT

A process for producing an electrically conductive, crosslinkable silicone elastomer composition includes an electrically conductive, crosslinkable silicone elastomer composition that contains 0.5% to 3.0% by weight of conductivity carbon black, 0.1% to 3.0% by weight of multiwalled carbon nanotubes (MWCNTs), and no solvent. In the case of one-component systems, all components are mixed in one or more steps and subsequently a pressure filtration through a metal fabric having a mesh size of at most 200 μm is carried out. In the case of two-component systems, in each case only the components of an A or a B composition are mixed in one or more steps and subsequently in each case a pressure filtration of the A or the B composition through a metal fabric having a mesh size of at most 200 μm is carried out.

The present invention relates to an electrically conductive, crosslinkable silicone elastomer composition as an electrically conductive printing ink in contactless printing processes for producing electrodes for sensors, actuators or EAP layer systems.

Electrically conductive printing inks are used for the production of printed electronics, in order, in electronic components, to apply electrodes over a large area or in a structured fashion to a substrate by way of any desired printing process. The printing of electrically conductive elastomers on an elastic scarrier (such as silicone, TPU) enables the construction of completely or partially clastic electronic components that retain their electrical properties virtually unchanged even in the case of stretching or compression. In addition, electrically conductive elastomer printing inks can be printed on flexible (but not stretchable) substrates, such as on PET, PE, PTFE or paper, in order, even in the case of sustained mechanical loading by repeated bending, to keep the mechanical damage to the printed electrode low and therefore to prevent a change in the electrical conductivity due to an increase in the resistance, for example. Conductive printing inks for printed electronics are known and some of them are also commercially available. They typically comprise at least one polymeric binder, at least one conductive component such as metal particles or carbon particles, and at least one solvent to adjust the viscosity. In principle, as filler, conductive carbon particles such as carbon black and carbon nanotubes (CNTs) have the disadvantage that they significantly raise the viscosity of the formulation, this making it much more difficult to print the ink, with the result that dilution solvents are typically used in order to reduce the effective concentration of the particles in the printing ink and to thus make it possible for the printing ink to be applied. U.S. Pat. No. 9,253,878 describes such a formulation based on a silicone elastomer, conductivity carbon black and CNTs, wherein the latter are characterized in that they have a thickness of at least 30 nm. The latter property imparts good printability in screen printing to the solvent-containing, conductive printing ink, this not being possible with thin CNTs (<30 nm). However, the formulation cannot do without solvent.

US2016351289 states that there must be a solvent content of at least 10% in a silicone-based conductive printing ink in order to be able to apply said ink. Typically, in the field of silicone printing inks use is made of organic solvents which can subsequently be completely removed only with great difficulty and which entail high costs for the user with respect to occupational safety and environmental protection.

CNT-containing silicone elastomers are known. CN103160128 describes silicone elastomers comprising both CNTs and carbon black. The silicone elastomers described in this document feature a high proportion of carbon black. Claimed is at least 3.7% by weight of carbon black; however, the examples show that a total filler content (CB+CNT) of at least 8.5% is needed to obtain good electrical properties such that the specific resistance is <20 Ohm*cm. No printing process using these compositions is disclosed.

Only a few solvent-free silicone-based printing inks are known: for example, US2014060903 describes a solvent-free, silicone-based, conductive printing ink that however does not contain any conductive particles with a high aspect ratio (such as carbon nanotubes=CNTs) and is therefore not suitable for stretchable applications. For stretchable applications, including dielectric elastomer sensors, actuators and generators, use is made of stretchable binders (elastomers) in combination with conductive anisotropic particles that have a high aspect ratio, typically CNTs. The high aspect ratio of the conductive particles ensures that, in contrast to spherical particles, the conductive particles can form a conductive network through the entire system at relatively low filler amounts, this network remaining even under stretching of the elastomer. Good electron conduction is therefore still guaranteed even in case of stretching of the elastomer.

The processes known in the prior art for applying silicone layers, particularly those suitable for the production of electrode layers and/or dielectric layers in actuators, sensors and other electroactive polymer layer systems, are limited in terms of their variability, application accuracy, throughput, and in terms of the component effectiveness and durability that are subsequently achieved.

One of the processes known in the prior art for the application of layers is that referred to as laser transfer printing. However, the application of this process has so far been limited to low-viscosity inks and dispersions, and metals.

By way of example, WO 2009/153192 A2 describes a process for producing conductive layers on semiconductor structures, where a metal powder dispersion is applied to a carrier and detached from the carrier onto a target by way of a laser beam.

By way of example, WO 2010/069900 A1 describes the laser transfer printing of ink.

WO 2015/181810 A1 describes a laser transfer process for printing metallic bodies. This involves selectively heating a metal film on a transparent carrier and positioning it in the form of drops.

It is accordingly an object of the present invention to provide a process for producing electrically conductive, crosslinkable silicone elastomer compositions which despite simultaneous use of conductivity carbon black and CNT having a high aspect ratio nevertheless do without the use of solvents while simultaneously exhibiting good application properties as printing ink in contactless application processes such as for example laser transfer printing and after application provide a smooth surface free from particles.

It has surprisingly been found in the present invention that an electrically conductive silicone elastomer composition based on conductivity carbon black (0.5-3% by weight) and MWCNT (0.1-3% by weight) may be employed as a printing ink without addition of a solvent to print electrodes for dielectric elastomer sensors and actuators when prior to the printing process said ink is passed through a metal fabric having a mesh size of not more than 200 μm (in particular not more than 100 μm) for pressure filtration. The resulting print image has a smooth surface and is free from specks.

It is undoubtedly surprising that the filter mesh does not immediately become blocked when a paste comprising particles having a high aspect ratio (ratio of length to diameter) of (L/B>10, preferably >100) is passed therethrough. This would have the result that the conductive particles would be removed from the paste and the filtration step would thus have an adverse effect on the electrical properties of the material. This is not the case: Both the electrical resistance of the uncrosslinked, filtered printing ink and the electrical characteristics of the sample vulcanized therefrom remain constant under stretching.

In order not to create an excessive number of pages in the description of the present invention, only the preferred embodiments of the individual features are specified hereinafter.

However, the expert reader should explicitly understand this manner of disclosure such that any combination of different levels of preference is thus also explicitly disclosed and explicitly desired.

The present invention therefore provides a process for producing an electrically conductive, crosslinkable silicone elastomer composition
containing:
   0.5% to 3.0% by weight of conductivity carbon black
   0.1% to 3.0% by weight of multiwalled carbon nanotubes (MWCNTs),
   NO solvent,
with the proviso that
a) in the case of one-component systems all components are mixed in one or more steps and subsequently a pressure filtration through a metal fabric having a mesh size of at most 200 μm is carried out or that
b) in the case of two-component systems in each case only the components of the A or B composition are mixed in one or more steps and subsequently in each case a pressure filtration of the A or B composition through a metal fabric having a mesh size of at most 200 μm is carried out.

The MWCNTs employed according to the invention preferably have an aspect ratio of L/B>10, especially preferably of L/B>100.

The metal mesh used in the pressure filtration preferably has a mesh size of at most 100 μm.

The methods for dispersing the conductive fillers, for mixing the components and for the pressure filtration and the apparatuses usable therefor are sufficiently well known to those skilled in the art from the prior art.

The dispersion is carried out for example using a roller mill, kneader or in particular a dissolver (high-speed mixer), wherein a scraper is typically also employed to achieve uniform distribution of the conductive fillers. It is preferable to use a planetary dissolver having a scraper. It is particularly preferable to use a vacuum planetary dissolver having a scraper and a beam stirrer. Dissolver disks having any desired arrangement and number of teeth may be used.

Base materials used for the silicone elastomer composition may in principle be all silicone elastomer compositions known in the prior art.

It is possible to employ for example addition-crosslinkable, peroxide-crosslinkable, condensation-crosslinkable or radiation-crosslinkable silicone elastomer compositions. Peroxide- or addition-crosslinkable compositions are preferred. Addition-crosslinkable compositions are particularly preferred.

The silicone elastomer compositions may have a one-component or two-component formulation. The silicone elastomer compositions are crosslinked here by supply of heat, UV light and/or moisture. Suitable silicone elastomer compositions include for example: HTV (addition-crosslinkable), HTV (radiation-crosslinkable), LSR, RTV 2 (addition-crosslinkable), RTV 2 (condensation-crosslinkable), RTV 1, TPSE (thermoplastic silicone elastomer), thiol-ene and cyanoacetamide crosslinkable systems.

In the simplest case the preferred addition-crosslinkable silicone elastomer compositions comprise:
(A) at least one linear compound comprising radicals having aliphatic carbon-carbon multiple bonds,
(B) at least one—preferably linear—organopolysiloxane compound having Si-bonded hydrogen atoms,
or, instead of (A) and (B) or in addition to (A) and (B),
(C) at least one linear organopolysiloxane compound comprising Si—C-bonded radicals having aliphatic carbon-carbon multiple bonds and Si-bonded hydrogen atoms, and
(D) at least one hydrosilylation catalyst.

To effect dispersing the component of the siloxane composition according to the invention may be added in any desired sequence and dispersed.

In a further preferred embodiment of the process the conductivity carbon black and MWCNTs are mixed into portions of the siloxane and optionally dispersed independently of one another, i.e. mixed in and dispersed in different mixing vessels, before the two mixtures (carbon black premixture and MWCNT premixture) are combined with mixing with any further components and optionally further dispersing. In a further embodiment of the process one or both premixtures may be produced using a roller mill.

It has proven advantageous to produce the carbon black premixture using a roller mill.

In a further preferred embodiment of the process conductivity carbon black and MWCNTs are together mixed into in the entirety or portions of the employed siloxane and subsequently dispersed together. Here too, a pre-produced carbon black premixture may be employed instead of the carbon black solid.

The amount of siloxane, conductivity carbon black and MWCNTs may be calculated such that it corresponds to the desired solids contents of conductivity carbon black and MWCNTs in the finished mixture or a so-called masterbatch may also be produced. In the case of a masterbatch either the siloxane amount and/or the carbon black and MWCNT amount is calculated so as to result in a higher solids content in the mixture than is subsequently required. Both carbon black and MWCNTs may be employed as solid or in the form of pre-produced mixtures. Once the dispersing is complete the concentrated solids dispersion may be diluted down to the solids target value with further siloxane. This can be done immediately after dispersing or later, optionally in a different mixing apparatus. Dilution may be effected using the same siloxane or a different siloxane.

The addition of MWCNT, carbon black and the components A) to D) may in each case be effected portionwise or by addition of the total amount independently of the precise process. Prior to the actual dispersing it may be advantageous to stir or mix the solids into the siloxane at a lower rotational speed of the mixing tools. This makes it possible to achieve a corresponding pre-wetting of the solids with siloxane.

The mixing vessel and thus the mixture present therein may optionally be temperature controlled during the dispersing, i.e. maintained at a target temperature by cooling or heating. The temperature is typically in a range from 0-200° C., preferably in a range from 20-100° C.

The process according to the invention may optionally be performed under vacuum. The dispersing, i.e. dispersing intervals including dispersing pauses, is preferably carried out under vacuum. The vacuum is typically <1000 mbar, preferably <800 mbar and particularly preferred <500 mbar.

It may further be advantageous to apply a vacuum after the dispersing. This may be carried out in the same apparatus as the dispersing or in a different apparatus. A vacuum is typically applied with stirring. The vacuum is typically <1000 mbar, preferably <800 mbar and particularly preferred <500 mbar.

The dispersing is then carried out at a high rotational speed of the dispersing tools and especially of the dissolver disk. The thus-achieved high power input results in the desired finely dispersed distribution of the conductive fillers such as for example MWCNTs or carbon black in the siloxane. A maximum power input of the mixing tools is essential to the dispersion result, and thus to an optimally high electrical conductivity of the conductive siloxane mixture. The maximum power input depends on the selected mixing tools, their geometric arrangement, the rotational speed, in particular of the dissolver disk, the temperature and the effective viscosity of the mixture, i.e. the viscosity of the siloxane which depends inter alia on the degree of polymerization of the siloxane and the filler amount added.

The present invention further provides the electrically conductive, crosslinkable silicone elastomer composition obtainable by the process according to the invention.

The invention further provides for the use of the conductive crosslinkable silicone elastomer composition according to the invention as electrically conductive printing ink in contactless printing processes for producing electrically conductive elastomers on elastic carriers.

If the thus-produced electrically conductive, crosslinkable silicone elastomer composition according to the invention is used as printing ink for example in a contactless printing process, this produces a printimage which has a smooth surface free of particles (specks). This is a crucial advantage if multilayer systems are to be produced, in which the conductive material is to be inserted between further layers, for example by way of lamination or overcoating.

Contactless printing processes have the advantage that the print substrate experiences the lowest possible mechanical load during the printing process. The electrically conductive, crosslinkable silicone elastomer composition according to the invention may be used as printing ink for other contactless printing processes, such as spraying processes, drop-on-demand processes or laser transfer printing (LIFT process). It is preferably used in laser transfer printing (LIFT process).

The electrically conductive, crosslinkable silicone elastomer composition according to the invention is particularly preferably suitable as printing ink for printing electrodes for dielectric elastomer sensors, actuators and generators and EAP layer systems.

### EXEMPLARY EMBODIMENTS

The examples that follow describe how the present invention may be performed in principle but without limiting said invention to what is disclosed therein.

The examples which follow were performed at ambient pressure, i.e. at about 1013 hPa, and unless otherwise stated at room temperature, i.e. about 23° C., or a temperature established upon combining the reactants at room temperature without additional heating or cooling.

### Chemicals

MWCNTs LUCAN BT1001M, LG Chem Ltd., average diameter according to manufacturer specifications: 10 nm

To produce the carbon black premixture 5% by weight of the high-conductivity carbon black Ketjenblack EC-600JD (obtainable from Nouryon) is incorporated into 95% by weight of ViPo 1000 using a three-roll mill.

ViPo 1000: Vinyldimethylsiloxy-terminated polydimethylsiloxane having a viscosity of 1000 mPa*s obtainable from Gelest Inc., product designation DMS-V31 (Gelest catalogue)

HPo 1000: Hydridodimethylsiloxy-terminated polydimethylsiloxane having a viscosity of 1000 mPa*s obtainable from Gelest Inc., product designation DMS-H31 (Gelest catalogue).

The crosslinker used was an α,ω-dimethylhydrogensiloxy-poly(dimethyl-methylhydrogen)siloxane (viscosity of 130-200 mm²/s; 0.145-0.165% by weight of H).

For one-component systems, the hydrosilylation catalyst selected was a platinum complex with phosphite ligands, as described in EP2050768B1 (catalyst 6). For two-component systems, WACKER® KATALYSATOR OL (obtainable from Wacker Chemie AG) was employed.

1-Ethynyl-1-cyclohexanol is available from Sigma Aldrich (CAS number: 78-27-3).

### Viscosity Measurement

The viscosity measurements were performed on an air-bearing-mounted MCR 302 rheometer from Anton Paar at 25° C. A cone/plate system (25 mm, 2°) with a gap size of 105 μm was used. The excess material was removed (trimmed) with a spatula at a gap distance of 115 μm. The cone was then moved to a gap distance of 105 μm so as to fill the entire gap. Before each measurement, a pre-shear is performed to erase the shear history resulting from sample preparation, application and trimming. The pre-shear is performed for 60 seconds at a shear rate of 10 s⁻¹, followed by a rest period of 300 seconds. The shear viscosity is determined by means of a step profile in which the sample is sheared at a constant shear rate of 1 s⁻¹, 10 s⁻¹ and 100 s⁻¹ for 100 seconds in each case. A reading is recorded every 10 seconds, resulting in 10 measurement points per shear rate. The average of these 10 measurement points gives the shear viscosity at the respective shear rate.

The storage modulus G′ was determined by means of an amplitude test. In this oscillation test, the amplitude γ is varied from 0.01% to 1000% (at an angular frequency ω of 10 s⁻¹, logarithmic ramp, 30 measurement points). The linear viscoelastic (LVE) region is typically found at low amplitude values, in which region G′, if plotted double-logarithmically against γ, has a plateau value. The plateau value is the storage modulus G′ to be determined.

### Resistance Measurement

A four-conductor measurement does not measure the contact resistance since the current is applied at two contacts and the voltage U of the current I_{U} that has already flowed through the sample is measured at two further contacts.

$$R = \frac{U}{{I}_{U}} [ Ω ]$$

The resistance R of unvulcanized siloxanes is measured with a multimeter model 2110 5½ digit from Keithley Instrument and a fabricated measuring apparatus made of pure PP and stainless steel (1.4571) electrodes. The measuring instrument is connected to the electrodes by means of brass contacts and laboratory leads. The measuring apparatus is a mold with defined dimensions for L×W×H of 16 cm×3 cm×0.975 cm, into which the siloxane is spread for measurement. The two outer flat electrodes are attached at a distance of 16 cm, thus ensuring that the current flows through the entire sample. The two point electrodes with a diameter of 1 cm are arranged in the base plate at a distance of 12 cm (l) and measure the voltage. The specific resistance is calculated from the measured resistance R using the following formula.

$$ρ = \frac{R \cdot h \cdot w}{l} [ Ω cm ] ,$$

with sample height h [cm], sample width w [cm] and electrode distance l [cm]
(here: h=0.975 cm, w=3 cm, l=12 cm)

### Change in Resistance Under Stretching

In accordance with ISO 37, the printing inks were vulcanized in the form of a 2 mm plate and the type 1 dumbbell specimen was punched. The test specimen is subjected to a four-conductor measurement. Said test specimen is clamped centrally between two electrically conductive clamping jaws, such that their distance from one another is 84.0 mm. The clamping jaws, representing the two outer electrical contacts, are structured, whereby a penetration effect into the material (piercing) is achieved as a result of the structure.

The two inner contacts are prepared by positioning two quick clamps 29.5 mm away from the closest clamping jaw in each case and at a distance of 25 cm from one another. The two inner measuring clamps are pretreated with silver conductive paste. The resistance thus measured without stretching (L=L₀) is R₀. The two outer clamping jaws additionally enable the uniaxial stretching of the test specimen and thus the measurement of the resistance R of the printed electrode in the case of stretching (L−L₀)/L₀=50%.

### Mixing Methods

The mixtures were produced in a Labotop 1LA from PC Laborsystem GmbH of 1 liter in capacity at a vacuum of 300 mbar and room temperature. The tools used were a dissolver disk (14 teeth, teeth at 90° to the disk, diameter 52 cm), a beam stirrer (standard tool) and a scraper with temperature measurement. For larger batches a laboratory mixer (Mischtechnik Hoffmann & Partner GmbH Andrä-Wördern, Austria) having a capacity of 10 L with a toothed dissolver disc (four teeth, diameter 98 mm), a beam stirrer and a scraper was employed. The double-walled stirred tank is adjusted to a jacket temperature of 19° C. with a thermostat.

To mix the components A and B a laboratory stirrer (IKA RW20) with a 3-blade propeller stirrer (R 1381) from IKA®-Werke Gmbh & Co. KG, Staufen, Germany was employed.

A three-roll mill from EXAKT (model 50 l) was employed. The roll nip was set to the minimum distance.

### Filtration

For pressure filtration the composition was transferred into a cylindrical steel vessel (capacity 5 L) open at the top and having a circular outlet (diameter 31.5 mm) in its base. Attached thereto is a biconical outlet, in the center of which a circular metal wire fabric (diameter 80 mm) is arranged. By lowering a pressure plate and at a pressing pressure of 50 bar the composition was pressed vertically out of the steel container and through the metal wire fabric. A hydraulic discharging unit from PC Laborsystem was used to lower the pressure plate.

Metal wire fabrics from PACO Paul GmbH & Co. KG or GKD-Gebr. Kufferath AG made of chromium-nickel steel (X5CrNi18-10, material no. according to DIN/DIN EN 1.4301) having a mesh size of 50 or 25 μm were employed.

### Example 1 Production of Masterbatch M1

In a laboratory mixer having a capacity of 10 L with a toothed dissolver disc (diameter 98 mm with four teeth), a beam stirrer and a scraper, MWCNT (36 g) and 1783 g of the carbon black premixture were mixed into ViPo 1000 (581 g) for 60 min at 1800 rpm (dissolver) and 50 rpm (beam stirrer). The double-walled stirred tank is adjusted to a jacket temperature of 19° C. with a thermostat. A homogeneous black paste having a specific resistance of 5.4 Ω*cm was obtained. The paste had a viscosity at a shear rate of 10 s⁻¹ of 296 Pa*s and a storage modulus G′ in the LVE range of 51 200 Pa.

### Example 2 Production of Masterbatch M2

MWCNT (1.0 g) and 50.9 g of the carbon black premixture were stirred (1 min) into ViPo 1000 (16.6 g) with a beam stirrer (80 rpm, Labotop without dissolver disc) and then twice incorporated with the three-roll mill. A homogeneous black paste having a specific resistance of 6.1 Ω*cm was obtained. The paste had a viscosity at a shear rate of 10 s⁻¹ of 280 Pa*s and a storage modulus G′ in the LVE range of 48800 Pa.

### Example 3 Production of Masterbatch M3

5.0 g of MWCNT were stirred (1 min) into 245 g of ViPo 1000 with a beam stirrer (80 rpm, Labotop without dissolver disc) and then twice incorporated with the three-roll mill. A homogeneous black paste having a specific resistance of 6.9 Ω*cm was obtained. The paste had a viscosity at a shear rate of 10 s1 of 80 Pa*s and a storage modulus G′ in the LVE range of 17000 Pa.

### Example 4 Production of Printing Ink 1a

In a Labotop 1LA laboratory mixer from PC Laborsystem GmbH with toothed dissolver disk (diameter 52 mm), 0.8% by weight of MWCNT (4.0 g) and 200 g of the carbon black premixture were mixed into a mixture of ViPo 1000 (108 g), HPo 1000 (154 g), crosslinker (20.0 g), Pt catalyst (0.4 g) and 1-ethynyl-1-cyclohexanol (30 mg) for 60 minutes at room temperature, 2000 rpm (dissolver) and 200 rpm (beam stirrer). The obtained paste was pressed through a metal fabric having a mesh size of 50 μm under pressure. A homogeneous, black paste was obtained.

### Example 5 Production of Printing Ink 1b

Printing ink 1b was produced analogously to printing ink 1a with the exception that the paste was pressed through a metal fabric having a mesh size of 25 μm.

### Example 6 Production of Printing Ink 1c (Non-Inventive)

Printing ink 1c was produced analogously to printing ink 1a with the exception that the paste was not pressed through a metal fabric.

### Example 7 Production of Printing Ink 2a

The masterbatch M1 from example 1 was diluted to afford a platinum-containing component A and a platinum-free component B:

To produce the A component 1000 g of the masterbatch MI were mixed with Vipo 1000 (855 g) and WACKER® KATALYSATOR OL (3.7 g) for 30 min with a beam stirrer (100 rpm, laboratory mixer without dissolver disc). The sample was subsequently pressed through a metal fabric (mesh size 50 μm) under pressure.

Component B was produced analogously to component A with the exception that 1000 g of the masterbatch M1 was mixed with HPo 1000 (465 g), crosslinker (260 g), Vipo 1000 (134 g) and 1-ethynyl-1-cyclohexanol (2.6 g). The sample was subsequently pressed through a metal fabric (mesh size 50 μm).

To produce printing ink 2b the components A and B were mixed in a 1:1 ratio for 1 min using a propeller stirrer (800 rpm). A homogeneous, black paste was obtained.

### Example 8 Production of Printing Ink 2b (Non-Inventive)

Printing ink 2b was produced analogously to printing ink 2a with the exception that the two components A and B were not pressed through a metal fabric before mixing. A homogeneous, black paste was obtained.

### Example 9 Production of Printing Ink 3a

The masterbatch M2 from example 2 was diluted to afford a platinum-containing component A and a platinum-free component B:

To produce the A component 30 g of the masterbatch M2 were mixed with Vipo 1000 (25.7 g) and WACKER® KATALYSATOR OL (0.11 g) for 30 min with a beam stirrer (80 rpm, Labotop without dissolver disc). The sample was subsequently pressed through a metal fabric (mesh size 50 μm) under pressure.

Component B was produced analogously to component B with the exception that 30 g of the masterbatch M2 was mixed with HPo 1000 (14.0 g), crosslinker (7.8 g), Vipo 1000 (4.02 g) and 1-ethynyl-1-cyclohexanol (78 μg). The sample was subsequently pressed through a metal fabric (mesh size 50 μm).

To produce printing ink 3a the components A and B were mixed in a 1:1 ratio for 1 min using a propeller stirrer (800 rpm). A homogeneous, black paste was obtained.

### Example 10 Production of Printing Ink 3b (Non-Inventive)

Printing ink 3b was produced analogously to printing ink 3a with the exception that the two components were not pressed through a metal fabric before mixing. A homogeneous, black paste was obtained.

### Example 11 Production of Printing Ink 4a

To produce the two-component printing ink a platinum-containing component A and a platinum-free component B were initially produced.

To produce the component A, in a laboratory mixer having a capacity of 10 L with a toothed dissolver disc (diameter 98 mm with four teeth), a beam stirrer and a scraper, MWCNT (15 g) and 743 g of the carbon black premixture were mixed into a mixture of ViPo 1000 (1097 g) and

WACKER® KATALYSATOR OL (3.7 g) for 60 min at 1800 rpm (dissolver) and 50 rpm (beam stirrer). The double-walled stirred tank is adjusted to a jacket temperature of 19° C. with a thermostat. The sample A was subsequently pressed through a metal fabric (mesh size 50 μm) under pressure. Component B was produced analogously to component A from MWCNT (15 g), 743 g of the carbon black premixture, HPo 1000 (465 g), crosslinker (260 g), Vipo 1000 (373 g) and 1-ethynyl-1-cyclohexanol (2.61 g). The sample B was subsequently pressed through a metal fabric (mesh size 50 μm) under pressure. To produce printing ink 4a the components A and B were mixed in a 1:1 ratio for 1 min using a propeller stirrer (800 rpm). A homogeneous, black paste was obtained.

### Example 12 Production of Printing Ink 4b (Non-Inventive)

Printing ink 4b was produced analogously to printing ink 4a with the exception that the two components were not pressed through a metal fabric before mixing.

### Example 13 Production of Printing Ink 5a

Production was carried out analogously to printing ink 1a with the exception that 192 g of masterbatch M3 (corresponds to 0.8% by weight of MWCNT) and 192 g of the carbon black premixture were employed in a mixture of ViPo 1000 (21.2 g), HPo 1000 (41.4 g) and crosslinker (33.6 g). The obtained paste was pressed through a metal fabric (mesh size 50 μm) under pressure. A homogeneous, black paste was obtained.

### Example 14 Production of Printing Ink 5b (Non-Inventive)

Printing ink 5b was produced analogously to printing ink 5a with the exception that the paste was not pressed through a metal fabric.

### Example 15 Production of Printing Ink 6a

Production was carried out analogously to printing ink 1a with the exception that 0.4% by weight of MWCNT (2.0 g) and 280 g of the carbon black premixture (corresponds to 2.8% by weight of carbon black in the final formulation) were employed in a mixture of ViPo 1000 (48.1 g) and HPo 1000 (150 g). The obtained paste was pressed through a metal fabric (mesh size 50 μm) under pressure. A homogeneous, black paste was obtained.

### Example 16 Production of Printing Ink 6b (Non-Inventive)

Printing ink 6b was produced analogously to printing ink 6a with the exception that the paste was not pressed through a metal fabric.

### Example 17 Production of Printing Ink 7a

Production was carried out analogously to printing ink 1a with the exception that 1.0% by weight of MWCNT (5.0 g) and 100 g of the carbon black premixture (corresponds to 1.0% by weight of carbon black in the final formulation) were employed in a mixture of ViPo 1000 (221 g) and HPo 1000 (153 g). The obtained paste was pressed through a metal fabric (mesh size 50 μm) under pressure. A homogeneous, black paste was obtained.

### Example 18 Production of Printing Ink 7b (Non-Inventive)

Printing ink 7b was produced analogously to printing ink 7a with the exception that the paste was not pressed through a metal fabric.

### Example 19 Production of Printing Ink 8a

Production was carried out analogously to printing ink 1a with the exception that 1.2% by weight of MWCNT (6.0 g) and 200 g of the carbon black premixture (corresponds to 2.0% by weight of carbon black in the final formulation) were employed in a mixture of ViPo 1000 (124 g) and HPo 1000 (150 g). The obtained paste is pressed through a metal fabric (mesh size 50 μm) under pressure. A homogeneous, black paste was obtained.

### Example 20 Production of Printing Ink 8b (Non-Inventive)

Printing ink 8b was produced analogously to printing ink 8a with the exception that the paste was not pressed through a metal fabric.

### Example 21 Production of Printing Ink 9a

Production was carried out analogously to printing ink aa with the exception that 1.5% by weight of MWCNT (7.5 g) and 100 g of the carbon black premixture (corresponds to 1.0% by weight of carbon black in the final formulation) were employed in a mixture of ViPo 1000 (221 g) and HPo 1000 (152 g). The obtained paste was pressed through a metal fabric (mesh size 50 μm) under pressure. A homogeneous, black paste was obtained.

### Example 22 Production of Printing Ink 9b (Non-Inventive)

Printing ink 9b was produced analogously to printing ink 9a with the exception that the paste was not pressed through a metal fabric.

### Example 23 Production of Printing Ink 10a

Production was carried out analogously to printing ink 1a with the exception that 1.2% by weight of MWCNT (2.4 g) and 100 g of the carbon black premixture (corresponds to 2.5% by weight of carbon black in the final formulation) were employed in a mixture of ViPo 1000 (28.3 g) and HPo 1000 (59.3 g), crosslinker (8 g), Pt catalyst (160 mg) and 1-ethynyl-1-cyclohexanol (12 mg). The obtained paste was pressed through a metal fabric (mesh size 50 μm) under pressure. A homogeneous, black paste was obtained.

### Example 24 Production of Printing Ink 10b (Non-Inventive)

Printing ink 10b was produced analogously to printing ink 10a with the exception that the paste was not pressed through a metal fabric.

### Example 25 Production of Printing Ink 11a

Production was carried out analogously to printing ink 1a with the exception that 2.0% by weight of MWCNT (10 g) and 300 g of the carbon black premixture (corresponds to 3.0% by weight of carbon black in the final formulation) were employed in a mixture of ViPo 1000 (25.3 g) and HPo 1000 (144 g). The obtained paste is pressed through a metal fabric (mesh size 50 μm) under pressure. A homogeneous, black paste was obtained. A homogeneous, black paste was obtained.

### Example 26 Production of Printing Ink 11b (Non-Inventive)

Printing ink 11b was produced analogously to printing ink 11a with the exception that the paste was not pressed through a metal fabric.

### Printing Experiments

The LIFT process was performed as described in WO2020156632. Printing was carried out with a commonly used laser engraving system from TROTEC Laser Deutschland GmbH. A system of the type Speedy 100flexx 60/20 with a dual laser source (60 W 10.6 μm CO2 Laser; 20 W 1064 nm fiber laser) is used. The carrier and printing compound carrier used are customary quartz glass sheets (300×300×3 mm) from GVB GmbH Solution in Glass, Germany. The printing composition film is applied using a ZAA 2300 automatic film-drawing unit with a ZUA 2000 universal applicator from Zehntner GmbH, Switzerland.

A homogeneous layer is centraly applied one-sidedly on a quartz glass sheet in a thickness of 60 um and in dimensions of 200×200 mm using the doctor blade system. The edge regions of the sheet remain free from printing compound. A silicone film (ELASTOSIL<®>-Film of 100 μm thickness, obtainable from WACKER Chemie AG) fixed to an uncoated glass pane via a water film is inserted into the cutting space of the laser as the surface to be printed. The coated sheet is placed on the first sheet with a spaceing of 200 μm with its coated side facing the uncoated sheet. The spacing is established with spacers such as for example 100 μm microscope slides. The master to be selected in the control software of the laser system is a two-dimensionally filled geometry without grey regions and shading. Further, a laser power in the fiber laser cutting mode of between 40-60% is sufficient in the case of a 20 W laser. The laser speed is to be selected at between 50% and 70%. The focal point should be about 4 to 4.5 mm above the interface between the coating and the quartz glass sheet. The selected geometries were thus able to be transferred by the laser onto the silicone film.

### Assessment of the Prints

The surface of the printed electrode was optically assessed. The layers printed with the printing inks 1a, 1b, 2a, 3a, 4a, 5a, 6a, 7a, 8a, 9a, 10a and 11a were smooth, shiny and free from protruding specks. These printing inks are thus particularly well-suited as electrode material for multilayer systems such as for example in dielectric elastomer sensors, actuators and generators. Layers printed with the printing inks 1c, 2b, 3b, 4b, 5b, 6b, 7b, 8b, 9b, 10b and 11b have surfaces with specks protruding from the layer and are thus unsuitable for multilayer systems.

The table that follows compares the amounts of MWCNT and carbon black used in the examples, the mesh sizes used for filtration and the results of the measurements.

| | | Carbon | | | | | |
|---|---|---|---|---|---|---|---|
| | MWCNT | black | Mesh | | | Spec. | |
| Printing | (% by | (% by | size | Viscosity | G′ | resistance | R/ |
| ink no. | weight) | weight) | [μm] | [Pas] | [kPa] | [Ω*cm] | R₀ |
| 1a | 0.8 | 2.0 | 50 | 79 | 11 | 8.8 | 1.6 |
| 1b | | | 25 | 79 | 11 | 8.8 | 1.6 |
| 1c | | | — | 79 | 11 | 8.8 | 1.6 |
| 2a | 0.8 | 2.0 | 50 | 66 | 8.7 | 11 | 1.6 |
| 2b | | | — | 69 | 8.5 | 11 | 1.6 |
| 3a | 0.8 | 2.0 | 50 | 77 | 9.3 | 9.5 | 1.6 |
| 3b | | | — | 75 | 9.0 | 9.5 | 1.6 |
| 4a | 0.8 | 2.0 | 50 | 80 | 10 | 9.5 | 1.6 |
| 4b | | | — | 80 | 10 | 9.5 | 1.6 |
| 5a | 0.8 | 2.0 | 50 | 81 | 9.5 | 9.0 | 1.6 |
| 5b | | | — | 81 | 9.5 | 9.0 | 1.6 |
| 6a | 0.4 | 2.8 | 50 | 67 | 6.7 | 18 | 1.8 |
| 6b | | | — | 67 | 6.6 | 18 | 1.8 |
| 7a | 1.0 | 1.0 | 50 | 51 | 6.3 | 19 | 1.2 |
| 7b | | | — | 51 | 6.3 | 19 | 1.2 |
| 8a | 1.2 | 2.0 | 50 | 100 | 19 | 6.8 | 1.2 |
| 8b | | | — | 100 | 18 | 6.8 | 1.2 |
| 9a | 1.5 | 1.0 | 50 | 80 | 15 | 5.1 | 1.2 |
| 9b | | | — | 79 | 15 | 5.1 | 1.2 |
| 10a | 1.2 | 2.5 | 50 | 151 | 23 | 7.8 | 1.2 |
| 10b | | | — | 151 | 24 | 7.8 | 1.2 |
| 11a | 2.0 | 3.0 | 50 | 300 | 88 | 3.9 | 1.1 |
| 11b | | | — | 300 | 88 | 3.9 | 1.1 |

1-6. (canceled)

7. Process for producing an electrically conductive, crosslinkable silicone elastomer composition
containing:
0.5% to 3.0% by weight of conductivity carbon black,
0.1% to 3.0% by weight of multiwalled carbon nanotubes,
no solvent,
with the proviso that
a) in the case of one-component systems all components are mixed in one or more steps and subsequently a pressure filtration through a metal fabric having a mesh size of at most 200 μm is carried out or that
b) in the case of two-component systems in each case only the components of an A or a B composition are mixed in one or more steps and subsequently in each case a pressure filtration of the A or the B composition through a metal fabric having a mesh size of at most 200 μm is carried out.

8. The process according to claim 7, wherein an electrically conductive, addition-crosslinkable silicone elastomer composition and contains the following components:
(A) at least one linear compound comprising radicals having aliphatic carbon-carbon multiple bonds,
(B) at least one—preferably linear—organopolysiloxane compound having Si-bonded hydrogen atoms,
or, instead of (A) and (B) or in addition to (A) and (B),
(C) at least one linear organopolysiloxane compound comprising Si—C-bonded radicals having aliphatic carbon-carbon multiple bonds and Si-bonded hydrogen atoms, and
(D) at least one hydrosilylation catalyst.

9. An electrically conductive crosslinkable silicone elastomer composition obtainable by a process according to claim 7.

10. A use of the conductive crosslinkable silicone elastomer composition according to claim 9 as an electrically conductive printing ink in contactless printing processes for producing electrically conductive elastomers on elastic carriers.

11. The use according to claim 10, wherein the contactless printing process is laser transfer printing.

12. The use according to claim 10, wherein the produced electrically conductive elastomers on elastic carriers are electrodes for dielectric elastomer sensors, actuators and generators and EAP layer systems.
